(19) United States
(12) Patent Application Publication
(10) Pub. No.: US 2013/0333616 A1
(43) Pub. Date: Dec. 19, 2013

(54) PLASMA PROCESSING SYSTEM WITH MOVABLE CHAMBER HOUSING PARTS

(71) Applicant: TEL Solar AG, Trubbach (CH)

(72) Inventors: Markus KLINDWORTH, Wangs (CH); Werner WIELAND, Malans (CH); Devendra CHAUDHARY, Jaipur (IN); Damian EHRENSPERGER, Basel (CH); Philipp WAGNER, Bad Ragaz (CH); Daniel LOCHER, Bad Ragaz (CH)

(21) Appl. No.: 13/919,759

(22) Filed: Jun. 17, 2013

Related U.S. Application Data
(60) Provisional application No. 61/660,910, filed on Jun. 18, 2012.
(60) Provisional application No. 61/663,122, filed on Jun. 22, 2012.

(51) Int. Cl. C23C 16/50; C23C 16/458

(52) U.S. Cl. CPC C23C 16/50; C23C 16/458
USPC 118/719; 118/729; 118/723 E

(57) ABSTRACT

A substrate processing system includes a vertically movable chamber section so that chamber sections are vertically separable to provide open and closed positions of a processing chamber or reactor, such as a plasma enhanced CVD chamber. In the open position, substrates are loaded and unloaded from the processing chamber, while in the closed position an enclosed processing volume is provided for processing substrates, particularly for processing large substrates (e.g., one square meter or larger) with a small gap (3-10 mm) between electrodes. Plural processing chambers can be provided and coupled to an actuator assembly for simultaneously vertically moving a chamber section or chamber portion of each processing chamber. Lift pins for receiving and positioning of substrates within the processing chambers can also be moved by the actuator assembly. A removable mounting arrangement is also provided for the lift pins.

### CROSS-REFERENCE TO RELATED APPLICATIONS

This application claims priority application to provisional applications 61/660,910, filed Jun. 18, 2012 and 61/663,122, filed Jun. 22, 2012, the entirety of which are incorporated herein by reference.

### TECHNICAL FIELD

The invention relates to plasma processing systems, and particularly plasma enhanced chemical vapor deposition systems (PECVD), however features of the invention could also be used in other types of plasma processing systems.

### BACKGROUND

PECVD systems are advantageously used, for example, in depositing thin films for flat panel displays, photovoltaic cells or modules, or OLEDs. For example, silicon or silicon compounds such as Si, SiOx, or SiN based films are formed using process gases (e.g., silane, dopants, hydrogen, etc.) that are excited to form a plasma.

FIG. 1 schematically represents a PECVD system having an enclosure or chamber 1 and a pair of essentially flat planar electrodes 2, 3. Such an arrangement is described, for example, in U.S. Pat. No. 6,228,438. The electrodes are connected to one or more suitable power supplies, such as an RF/VHF power supply (not shown) by connectors represented at 7, 8. In addition, a substrate 4 is positioned on the electrode 3. A gas supply 5 and exhaust 6 are schematically represented, however it is to be understood that the supply and exhaust can have various forms.

Such an arrangement can be used, for example, to deposit silicon compounds on glass substrates, for example, substrates having dimensions of 1100-1300 mm or 1.4 m², by way of example. As shown, an inter-electrode gap IEG is provided as a space between the two electrodes, while the plasma gap PG is provided between the top of the substrate 4 and the bottom of the upper electrode 2. By way of example, a standard gap size can be approximately 30 mm, however very small gaps of below 10 mm can be desirable. As should be apparent, the plasma gap PG is effectively the IEG minus the thickness of the substrate 4.

Such systems can be in the form of single reactor or single chamber systems, but also can be part of larger systems having multiple reactors which simultaneously perform CVD processes on other substrates in parallel. In addition, such chambers or reactors can be provided in in-line or cluster configurations. Two types of reactor arrangements are also commonly known, including a one-reactor-single-wall chamber type, and a box (or boxes)-in-box arrangement. In the one-reactor-single-wall chamber type, the walls of the reactor or chamber form the vacuum or reduced pressure volume within which the processing takes place, and an ambient or approximately atmospheric pressure surrounds the outside of the reactor. In the box-in-box arrangement, the reactor box provides a processing region that is located within the outer walls of another chamber to form a separate outer enclosure, and the outer enclosure can be maintained at a reduced pressure. In addition, plural reactors can be provided in the outer chamber for batch processing of plural substrates. See, for example, U.S. Pat. Nos. 4,989,543 and 5,693,238.

In such arrangements, it is constantly an objective to provide high quality, consistent and cost effective performance from a standpoint of producing Si and Si compound layers or films having a low occurrence of defects, high throughput and deposition rates, and efficient, cost effective performance from a standpoint of cost of the equipment and cost of operation and/or maintenance. To achieve high deposition rates, high RF power and/or high RF frequencies are used. However, this also intensifies ion bombardment onto the substrate, and thus, could produce defects. In addition, a high deposition rate can require a high concentration of Si atoms in the plasma, for example, with a higher working gas pressure. High process pressures can be advantageous in reducing the intensity of ion bombardment, however particle generation can also be a problem as a result of undeposited Si particles. Particles or other impurities, defects or inhomogeneities can result in poor or unacceptable layers or films.

One variable which can be used to control or improve performance is the inter-electrode gap (IEG). By reducing the inter-electrode gap, for example, to the extent that the order of magnitude of the mean free path for SiHx-radical collisions and Poly-SiH₂-molecule collisions become comparable to the gap size, agglomeration of Si atoms to form particles or grains can be avoided. However, there can be mechanical, electrical and other process constraints associated with reducing the gap, particularly when considering the size of the substrates being processed are often one square meter in size or larger. Thus, disadvantages or challenges can also be associated with reducing the IEG. Trade-offs associated with the desire to achieve a smaller gap and the challenges presented have resulted in PECVD systems with an IEG of less than 20 mm but greater than 10 mm.

One problem associated with reducing the gap (IEG) is that the equipment used in loading and unloading of the substrates must have sufficient space to operate. WO 2006/056091 discloses a reactor arrangement in which the reactor is separated horizontally into two parts to allow access by a loading fork. The loading forks insert the substrates into the reactors, lift pins rise to remove the substrates from the forks, and the loading forks are retracted. The lift pins are then retracted to deposit the substrate on a lower electrode for processing. In addition, the two parts of the reactor are moved together to close the processing space. However, such an arrangement can be undesirable for many reasons including the need to move heavy parts, which can be difficult particularly within a vacuum for a box-in-box type system. In addition, such an arrangement can be complicated and/or expensive due to the need to interface movable reactor parts with utilities such as process gas handling, heating/cooling connections, pumping, and RF/VHF power—while keeping the chamber secure from RF/VHF power leakage in the closed position.

An additional problem with prior art arrangements resides in the lift pins used in loading substrates as discussed above. In particular, such pins should be made small in cross-section so as to avoid or reduce any adverse impact on the lower electrode, in terms of the uniformity of electrical properties and/or thermal properties of the lower electrode. However, with the size of the pins kept small, they can wear or fail with repeated use. Lift pins can encounter greater frictional stress as a result of the vacuum environment, and the pins can be subjected to additional stresses as a result of exposure to heat and chemicals, which also can cause premature fatigue or wear. If the pins should become defective, it can lead to a crash or damage to the glass substrate, which is unacceptable. Thus, pins must be able to be replaced. Further, the replacement must be relatively simple and not consume substantial amounts of time, particularly given that a system (having multiple chambers or reactors) could have on the order of 480 lift pins, for example.

### SUMMARY OF INVENTION

The invention provides advantageous arrangements which can be utilized in plasma processing equipment, particularly PECVD equipment. The features of the invention can be particularly advantageous for PECVD equipment used in making photovoltaic or solar cell components, however, features of the invention could also be used in other types of plasma processing equipment or equipment used for other products. The invention is also advantageous for processing large substrates, for example, one square meter or larger, with small gap sizes. For example, the arrangement can be advantageously used with an IEG of 3-10 mm, and a PG of 2-8 mm and more preferably a PG of 3-7 mm. Alternately, for example, the IEG can be 3-16 mm, with a PG of 2-14 mm, and more preferably with a PG of 3-13 mm. However, features of the invention could also be used with different substrate and gap sizes. The invention is also advantageous in a fixed gap system, in which the gap spacing is fixed when the chamber is in the assembled and closed position. However, features of the invention could also be used in a variable gap system in which the gap spacing can be changed or adjusted by an adjusting expedient (e.g., an actuator). In addition, the invention is advantageous for deposition systems such as PECVD systems, however, the invention could also be used with other types of systems such as etching, or cleaning systems, for example.

In accordance with one of the features of a preferred example, a reactor is provided which is vertically separable into two parts (upper and lower), to thereby ease loading and unloading of substrates therein when the parts are separated, while also allowing for a small gap between the upper and lower electrodes when the two parts are brought together and substrates are processed. Such an arrangement is especially advantageous in processing large substrates (e.g., one square meter or larger) while processing with a small inter-electrode gap. With this arrangement, an upper portion of the reactor is moved relative to the lower portion (or vice versa) to allow for loading and unloading of the substrate onto lift pins of the reactor. Once the substrate is loaded, the lift pins can be lowered to set the substrate on the lower electrode, and the two parts of the reactor can be brought together or closed so that processing can proceed with a small inter-electrode gap and a small plasma gap.

In accordance with one preferred example, the upper portion of the reactor is movable while the lower portion is fixed. Thus, the upper portion can be easily moved to provide additional space for loading/unloading of substrates. In accordance with another feature, the same vertical movement or actuation for moving the upper portion of the reactor is also used to move the lift pins. This arrangement ensures coordinated operation, and moreover, can reduce the number of required actuators.

In a particularly preferred example, a system is provided which includes plural reactors stacked one above the other, with each of the stacked reactors coupled to a common actuator which opens or moves the upper portion of each of the reactors at the same time (or at least partially overlapping with the time) the lift pins are raised. Alternately, the lower portions of the reactors could be moved, or a combined movement of both parts could be used, however. A loading fork assembly having plural loading forks thereon (for the respective plural reactors) can then move substrates into the reactors, and the lift pins remove the substrates from the loading forks. The reactors are then closed while the lift pins are lowered.

In accordance with another advantageous aspect of the invention, a mounting arrangement is provided for lift pins, which allows the pins to be easily removed and replaced in a simple, efficient manner which is not time consuming. As a result, the lift pins can be regularly maintained and replaced so that the risk of a glass crash is minimized or reduced, and downtime as a result of maintenance is also reduced.

Additional features and advantages will become apparent from the description herein.

As will be apparent from the description herein, the present invention includes a number of advantageous features. It is to be understood that systems can be constructed which might incorporate certain features but not others, and that variations and modifications can be implemented. The invention is therefore not limited to the particular examples described.

### BRIEF DESCRIPTION OF THE DRAWINGS

A better appreciation of the invention will become apparent from the description herein, particularly when considered in conjunction with the drawings in which:

FIG. 1 is a schematic representation of a conventional PECVD arrangement;

FIGS. 2A and 2B illustrate an example of a reactor in accordance with the present invention in open and closed positions;

FIGS. 3A and 3B illustrate an alternate example of an embodiment of the invention in closed and open positions;

FIG. 4 schematically represents a gas flow arrangement in accordance with an example of an embodiment of the invention;

FIGS. 5A and 5B illustrate a stacked arrangement of reactors in accordance with the present invention in closed and open positions; and

FIGS. 6A-6C are perspective views illustrating an advantageous removable mounting arrangement for lift pins in accordance with the present invention.

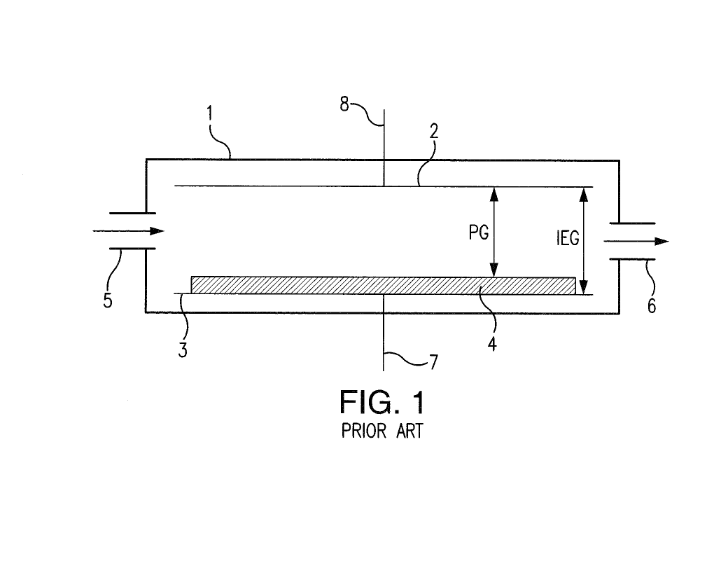

### DETAILED DESCRIPTION

A better appreciation of the invention will be apparent from the following detailed description, in which like reference numbers are used for the same or similar parts throughout the different views. It is to be understood that the illustrated embodiments are provided as examples, because variations are possible as would be understood by those skilled in the art. In addition, although the examples are provided as a combination of elements, it is to be understood that the invention could be practiced with a subset of such elements, and therefore, features of the illustrated examples should not be considered as required or essential unless so described.

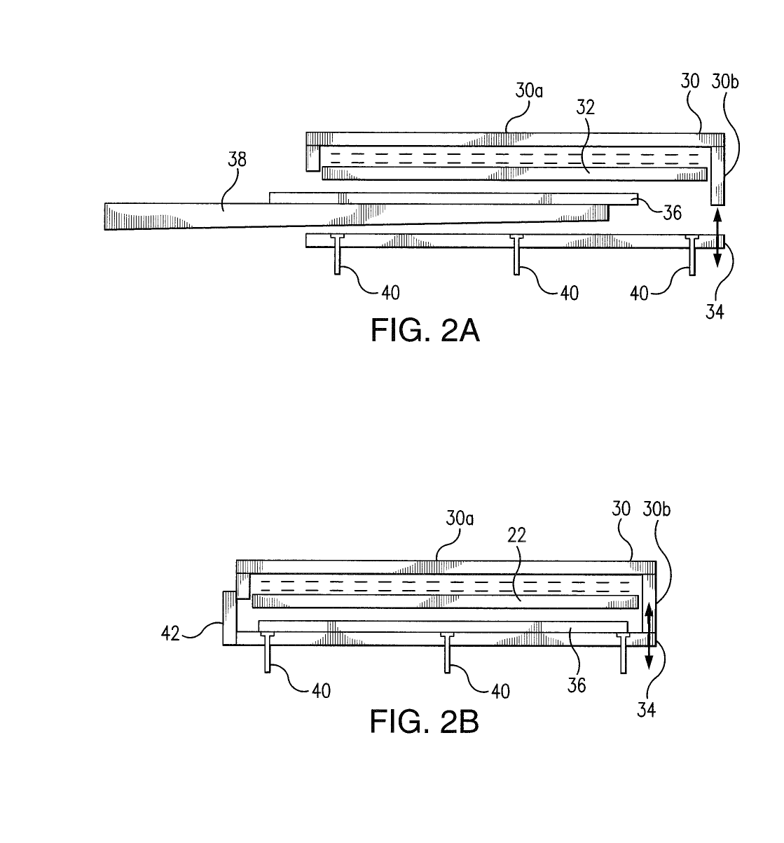

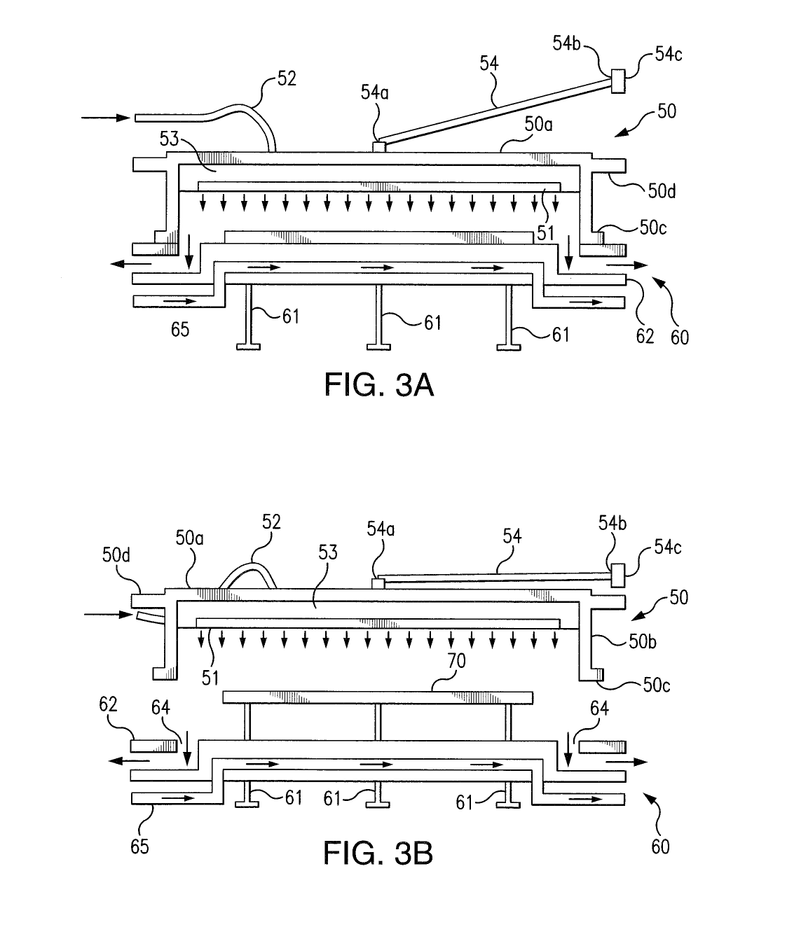

FIGS. 2A and 2B illustrate a first example of the invention in which the lower portion of the reactor is vertically moved relative to the upper portion to allow for insertion and removal of substrates. In the illustrated example, a lower electrode 34 is provided, and lift pins 40 are associated therewith, so that the lift pins can extend through the electrode. When the lift pins 40 are raised, they lift a substrate 36 from the loading forks so that the substrate is received on the lift pins 40. After the loading fork is removed, the lift pins can then be retracted to deposit the substrate 36 on the electrode 34. The upper portion of the reactor 30 also includes an electrode 32 associated therewith. In the preferred form, the upper electrode 32 is in the form of a shower head (discussed further below with reference to the example of FIGS. 3A and 3B) so that the process gases are injected through the electrode 32. In addition, in the illustrated example, the electrode 32 is a powered electrode, while the electrode 34 is a counter electrode or ground electrode. However, it is to be understood that different arrangements for application of the power are possible, for example, with power applied to the lower electrode or to both electrodes. The upper portion 30 of the reactor includes a top portion 30a as well as sidewall portions 30b which form a reactor box when brought together with the lower portion of the reactor having the lower electrode 34. In addition, a reactor door 42 can be provided (FIG. 2B) which is movable between open and closed positions. FIG. 2A shows the arrangement in the open position in which the upper portion 30 is separated from the lower portion 34. As should be apparent, in this position, sufficient space is provided for insertion of the loading forks 38 so that the loading forks can place the substrate 36 on raised lift pins 40 (or the lift pins are raised to lift the substrate from the loading fork positioned in the reactor). Thereafter, the upper portion 30 and lower portion 34 can be brought together and the lift pins can be retracted to place the substrate 36 on the lower electrode 34. In addition, the reactor door 42 is closed to thereby form an enclosed reactor volume. In a presently preferred form, this arrangement is provided in a box-in-box system which is discussed further hereinafter. However, it is to be understood that the invention could also be used in other types of systems. As should be apparent from FIG. 2B, with this arrangement, a very narrow inter-electrode-gap (IEG) can be achieved. By way of example, and not to be construed as limiting, in accordance with preferred gap sizes of embodiments described herein, an IEG of 3-10 mm is preferred. A typical substrate thickness can be approximately 0.1-4 mm. The plasma gap (PG) (the space from the top of the substrate to the upper electrode) can preferably be 2-8 mm, and more preferably 3-7 mm, for example. It is to be understood that other gap sizes could be used.

Although not illustrated in FIGS. 2A and 2B, suitable power connections and gas supply and exhaust utilities are provided, and such features are discussed in further detail in connection with additional examples described hereinafter. By way of example, the arrangements described herein can be used for plasma processing with a capacitively coupled plasma (CCP), with process pressures of, for example, 10-35 mbar. However, it is to be understood that other process pressures could also be used, including pressures below 10 mbar.

In the arrangement described above, the lower portion of the reactor moves. However, it also would be possible to have both the upper and lower portions movable. In addition, as discussed below, in accordance with another preferred example, the upper portion of the reactor is movable while the lower portion is fixed. To provide movement, a suitable coupling (such as a rod or bar) is connected to a suitable actuator mechanism, such as a pneumatic or hydraulic actuators, an electric motor, a spindle/gear or rack/pinion, or other actuators can be used for opening and closing of the reactor. Where plural reactors are provided, individual actuators could be utilized for each reactor. However, in accordance with a particularly preferred form, a common actuator is provided for simultaneous movement of the reactor parts relative to each other for a plurality of reactors at the same time. An example of such an arrangement is discussed further hereinafter.

FIGS. 3A and 3B illustrate an example of the invention in the form of a separable chamber or reactor. In the preferred form, the reactor is in a box-in-box configuration or, in other words, the reactor is within a larger vacuum chamber. However, the invention need not be limited to such an arrangement.

In accordance with the FIGS. 3A and 3B arrangement, the two separable reactor parts can be separated to allow loading and unloading of the substrate, and thereafter, the parts are closed to form a narrow gap reactor. In accordance with an example, the parts can be arranged such that the two parts include a first very light weight upper part having only connections for required utilities, preferably in the form of flexible and/or articulatable connections, whereas the second non-movable lower part has the heavier components associated therewith. However, the invention could also be used where the two parts have about the same weight, or even where the movable part is heavier.

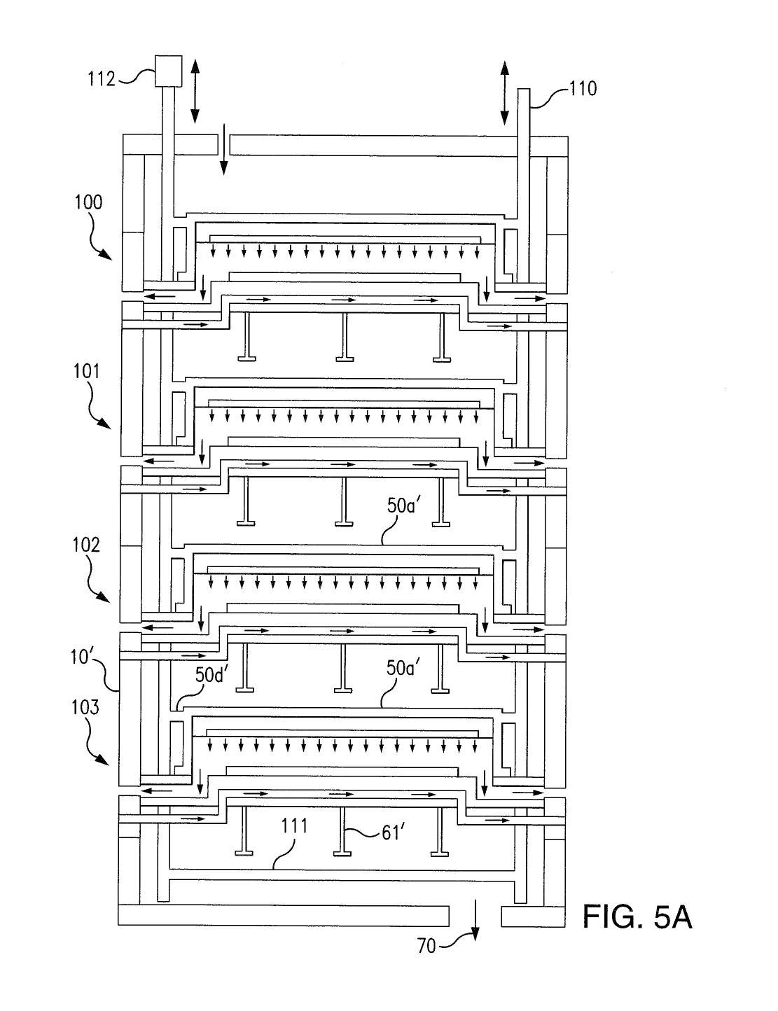

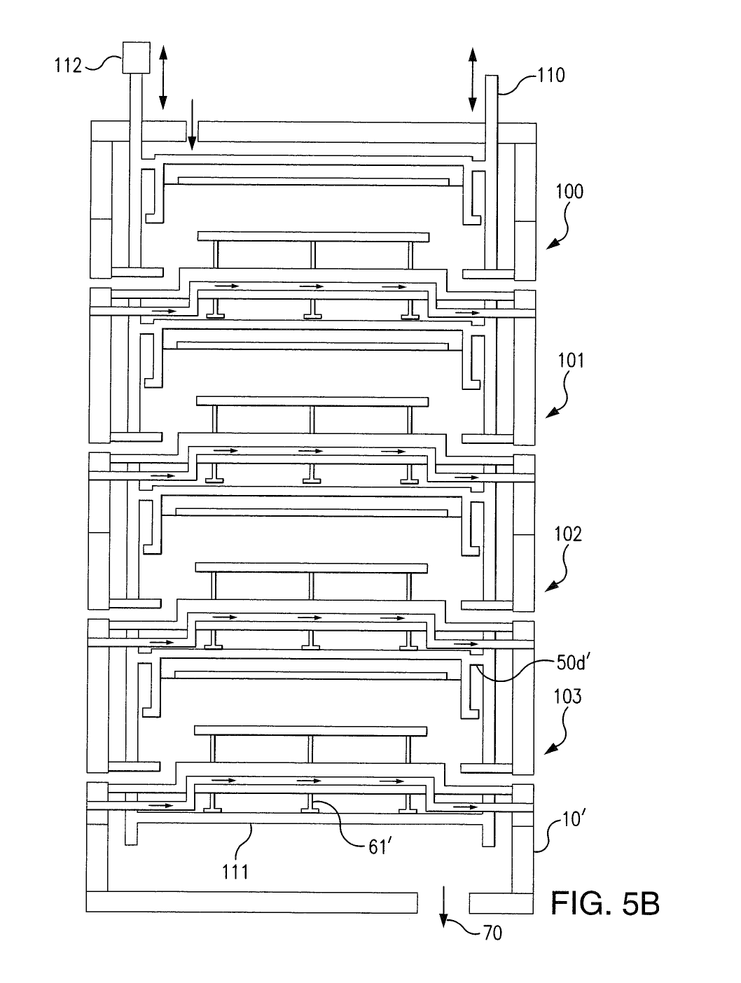

FIG. 3A illustrates the arrangement in the closed position for processing, while FIG. 3B illustrates the arrangement in the open position, with the lift pins raised to hold the substrate. In the illustrated arrangement, the upper portion of the reactor 50 is movable, while the lower portion 60, with which the upper portion abuts or mates in the closed position, is stationary. The upper portion has relatively light weight components, preferably with only connections for required utilities coupled thereto. In addition, the utilities connections can be easily moved, so that the arrangement is light weight and easily movable. This also assists in providing a common actuator for plural reactors as discussed later in connection with FIGS. 5A-B. The lower portion of the reactor 60 is fixed in this example.

For loading a substrate, the upper portion of the reactor 50 is in the raised position, and the lift pins 61 are in the raised position. The loading fork is inserted to position a substrate just above the lift pins 61. The lift pins are then raised to remove the substrate from the loading forks, and the loading forks are removed. The lift pins are then lowered to place the substrate on the lower electrode. It is to be understood that different combinations of movement could be used to allow the substrates to be received by the lift pins. For example, as an alternative to the lift pins lifting the substrates from the loading forks, the loading forks could be lowered to place the substrates on raised lift pins. Presently, it is preferred to use the lift pins to lift the substrates from the loading forks. As discussed later, in a preferred form, plural reactors are provided in a stacked arrangement. In this case, a loading system can have plural loading forks to simultaneously load plural substrates into respective plural reactors.

As shown, an upper electrode 51 is associated with the upper reactor box 50 and moves therewith. In the illustrated preferred example, the upper electrode 51 is in the form of a shower head such that process gases exit through a plurality of apertures associated with upper electrode as illustrated by the arrows beneath the upper electrode 51. One or more gas inlet tubes or conduits 52 are provided to supply one or more process gases. The gas supply tube or conduit 52 is preferably flexible to accommodate movement of the upper reactor portion 50. By way of example, a space 53 is provided between the top of the upper electrode 51 and the top inner surface of the upper reactor box portion 50, which allows for pressure equalization to thereby provide a more uniform gas flow from the shower head electrode 51. It is to be understood that, where plural process gases are provided, they can be mixed upstream of the gas inlet tube 52 and supplied by way of the single gas inlet tube 52, or alternately, gases can be provided through plural inlet tubes 52 and mixed within the region 53. It is to be understood that alternate shower head or gas injection configurations could also be used, however, the illustrated arrangement is presently preferred.

A power conductor is provided as shown at 54 so that the upper electrode is a powered electrode in the illustrated example. In the preferred form, the conductor is for RF/VHF power. Due to the requirements to supply a high frequency power, in the illustrated arrangement, a hard or rigid conductor 54 is illustrated, and the movement of the upper reactor box portion 50 is accommodated by one or more articulations as illustrated at 54a, 54b. Alternately, the articulations can be replaced with a flexible or semi-flexible connector, such as a flat ribbon or a flexible plate connector. As should be apparent, although the connectors 52, 54 for gas and electrical power are coupled to the upper reactor box, the gas source and power source themselves are not, and thus can be at a fixed location without needing to move with the upper reactor box. This allows the upper reactor box 50 to be light weight, making movement of same more desirable, particularly where a common actuator moves plural upper reactor box portions as discussed later. The power supply (not shown) can be connected to a flange 54c which is at a fixed location, and at which the power supply is coupled to the conductor 54, and movement of the upper reactor box 50 is accommodated by the articulations 54a, 54b of the conductor 54. The gas supply source (not shown) can also be at a fixed location, and movement of the upper reactor box is accommodated by the flexibility of the flexible tube 52 in the illustrated example.

The upper reactor box 50 includes a top 50a as well as depending side walls 50b which form the side walls enclosing the reactor box in the closed position. In addition, a flange portion 50c can be provided to ensure an adequate seal with the lower portion 60. Suitable seals or interlocking expedients can be associated with the flange 50c and/or the lower portion of the reactor box 60 to ensure a good seal in the closed position. However, as discussed further hereinafter, particularly where the arrangement is in a box-in-box system, it is not necessary to have a completely gas tight seal, because any gases that might escape from the reactor into the outer chamber can be exhausted from the outer chamber which encloses a plurality of such reactors. Another flange is illustrated at 50d, and this flange provides for coupling of the upper reactor box portion to an actuator assembly for moving the upper box portion 50 as discussed hereinafter.

The lower assembly includes lift pins 61 which extend through the lower electrode 62, so that in the open position, the lift pins can be raised to hold a substrate 70.

In the illustrated example, the upper electrode can be powered while the lower electrode 62 is grounded, however alternate arrangements can be provided, for example, in which a lower electrode is powered while the upper electrode is grounded, or alternately, it is possible to supply power to both upper and lower electrodes.

As also shown, exhaust passageways 64 are provided to exhaust gases from the reactor, with the passageways 64 connected to a vacuum pump downstream of the exhaust passageway 64 (not shown). In addition, one or more temperature control expedients are associated with the lower assembly 60. In the illustrated arrangement, at least one channel is provided for the flow of a temperature control medium, such as a liquid coolant, as shown at 65. A thermostat and suitable controllers can also be provided. The temperature control medium flowing through passage 65 can provide for heating and/or cooling. In addition, as an alternative, or in combination with the use of a cooling medium, electrical heating can be provided to supply heat. When both a temperature control medium and electrical heating are provided, the electrical heating can provide tuning (e.g., to improve uniformity and/or more precise control) of the temperature control provided by the cooling medium passing through passageway 65. However, the use of a liquid transfer medium alone is suitable for most or many applications.

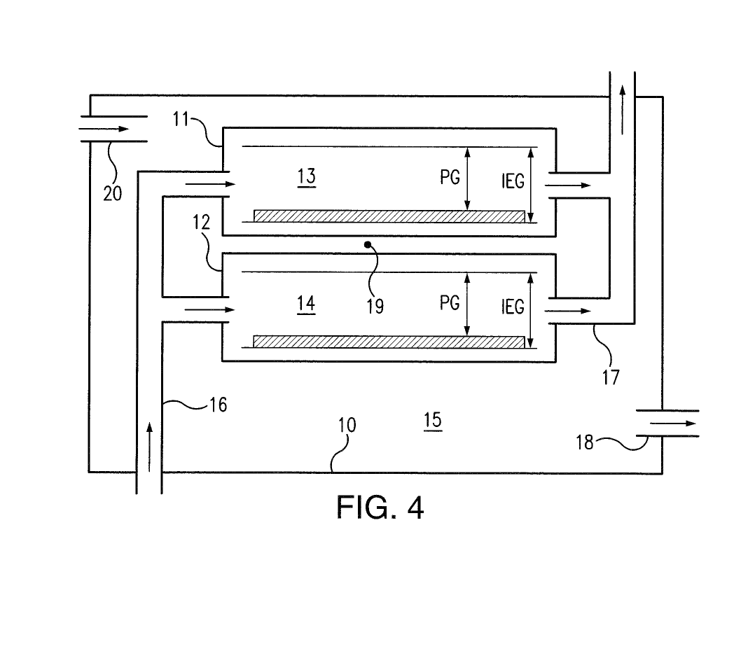

Processing temperatures can range, for example, from 50° C. to 300° C. Various temperature control mediums or fluids can be utilized, depending upon the processing temperature. For example, water can be suitable for processes lower than 100° C., while a water-glycol-mixture can be utilized for temperatures up to approximately 160° C. For higher temperatures, oils can be used. Because the bottom or lower portion of the reactor 60, 62 is temperature controlled, but the top is not, the temperature of the upper portion 50 of the reactor can oscillate. Cooling of the reactor top and the dampening of temperature oscillation of the top can be provided by thermally coupling the bottom of a reactor to an adjacent top of another reactor positioned underneath, as will now be discussed with reference to FIG. 4.

FIG. 4 schematically represents gas flows and gas connections in a box-in-box arrangement in which plural reactors are stacked above one another in accordance with the invention. As FIG. 4 is a schematic representation, details regarding the opening and closing of the reactors are omitted, however this arrangement can be used with movable reactor portions as discussed earlier. In addition, it is to be understood that the gas flow connections are schematic and thus, for example, while the process gas inlets are provided from a conduit 16 represented as entering the sidewalls of the reactors 11, 12, in an actual arrangement, the process gasses can enter through a tope of the reactors and be injected through a shower head as discussed earlier. As also discussed earlier, reactors 11, 12 can be stacked, and can be provided in a box-in-box arrangement, with an outer chamber 10 surrounding the reactors 11, 12. As shown, process gases are supplied to the reactors via inlet conduit 16, and gases are exhausted through exhaust conduit 17.

As discussed earlier, is not necessary for the reactors 11, 12 to be completely gas tight, because any gases which might escape from the reactors enters the volume 15 of the chamber 10. The volume 15 of the chamber 10 can be kept at the same pressure as the pressure in the reactor volumes 13, 14 in the preferred arrangement, so as to minimize the exchange of gases between the volumes. A suitable gas can be pumped through the inlet 20 of the chamber 10, however, as an alternative, only an exhaust pump can be utilized for the exhaust outlet 18. By way of example, an inert gas can be provided in the outer chamber 10, or alternately, one or more gases which are also used as a process gas could be used. Separate pumping and pressure control can be provided for the volumes 13, 14 as compared with the volume 15, or if desired, a common pressure control or exhaust pumping can be utilized. Separate pressure control systems can be desirable, for example, to allow different operations such as for flushing of plasma products or contaminants from the reactors 11, 12 when processing is not being performed. Thus, it is to be understood that alternate pumping arrangements could be used, for example, with one pump used for both the reactors and outer chamber, separate pumps for the outer chamber and the reactors, or with one pump connected only the reactors.

As discussed earlier in connection with FIGS. 3A and 3B, because the respective bottoms of reactor chambers 11, 12 are cooled, but the top portions are not, the top portion can become hotter and the temperature thereof can oscillate over different process cycles. To dampen the temperature variation and provide cooling of the upper portions of the reactors, the bottom of an upper reactor 11 can be thermally coupled to the top of a lower reactor 12. This can be achieved, for example, by injecting a gas into a region between the two reactors as shown at 19. The thermally conductive gas in the space between the reactors promotes thermal coupling between the reactors, and particularly between the bottom or lower portion of one reactor and the top or upper portion of another adjacent reactor. By way of example, the injected gas can be hydrogen, and preferably is a gas which is also an ingredient of the deposition process. The pressure can be boosted, for example, greater than 5 mbar, and more preferably, greater than 10 mbar, to provide thermal coupling between the reactors.

FIGS. 5A and 5B illustrate an arrangement of plural stacked reactors of the type discussed previously with reference to FIGS. 3A and 3B. In the illustrated arrangement, a box-in-box system is provided, with an outer chamber 10′ as discussed earlier in connection with FIG. 4. The outer chamber 10′ can be exhausted as represented by arrow 70. In the illustrated example, four reactors 100-103 are provided, however, it is to be understood that the number of reactors can vary. In addition, a common rod or frame assembly 110 is provided which is interconnected to each of the reactors so that, in opening and closing of the reactors (moving of the upper reactor portion relative to the lower portion as discussed earlier), each of the reactors can be opened and closed together. The frame 110 can be moved by a suitable pneumatic or hydraulic actuator schematically represented at 112, or alternately, any suitable actuator arrangement can be utilized, such as an electric motor.

In accordance with an additional advantageous feature of the arrangement of FIGS. 5A and 5B, the movement utilized in separating the upper and lower reactor parts is also utilized for moving of the lift pins. This ensures coordinated movement and also reduces the number of actuators needed. As shown, at the bottom of each frame or actuator assembly 110, a plate or abutment 111 is provided to serve as a connection between the frame assembly and the lift pins of the lowermost reactor 103. As a result, as can be seen in comparing FIGS. 5A (closed position) and 5B (open position) as the frame 110 is moved upwardly, the connection 111 to the actuator assembly 110 moves the lift pins 61′ upwardly. Thus, the same movement used for raising the upper chamber part also provides for actuation or lifting of the lift pins 61′. The flanges 50d′ of the respective upper chamber parts are also connected to the actuator frame 110 to move with the actuator frame 110. Although the connection 111 is provided for the lowermost reactor, in accordance with an additional advantageous feature of the invention, a separate connection 111 for the chambers (100-102) above the lowermost chamber (103) is not needed, and the top of the reactors can provide the connection to raise the lift pins as shown. Thus, as the upper portion of a reactor box is raised, it raises the lift pins of a reactor positioned above that reactor. By way of example, as an alternative, additional connectors like connector 111 can be provided for coupling the frame 110 and the lift pins 61′ for the reactors (100-102) above the lowermost reactor, instead of actuating the lift pins of the reactors with the top portion of an underlying reactor. In the illustrated example, as shown in FIG. 5A, there is a gap between the connector 111 and the bottom of the lift pins, with a gap also between the top of reactors 100-102 and the lift pins above same. As a result, with this arrangement, the upper portions 50a′ of the reactors move first, and then the raising of the lift pins begins. The gap can be eliminated or the size of the gap can vary. Other arrangements can also be used for connecting the lift pins to the frame 110, and if desired, the lift pins could be actuated separately from movement of the upper portions 50a′ of the reactors.

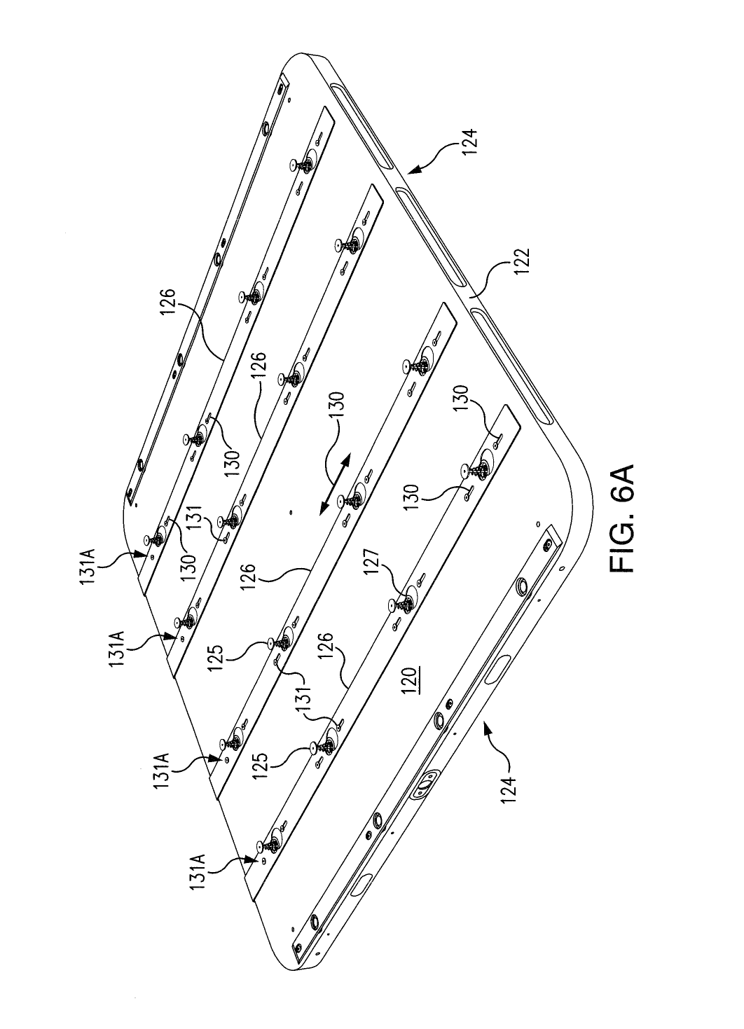

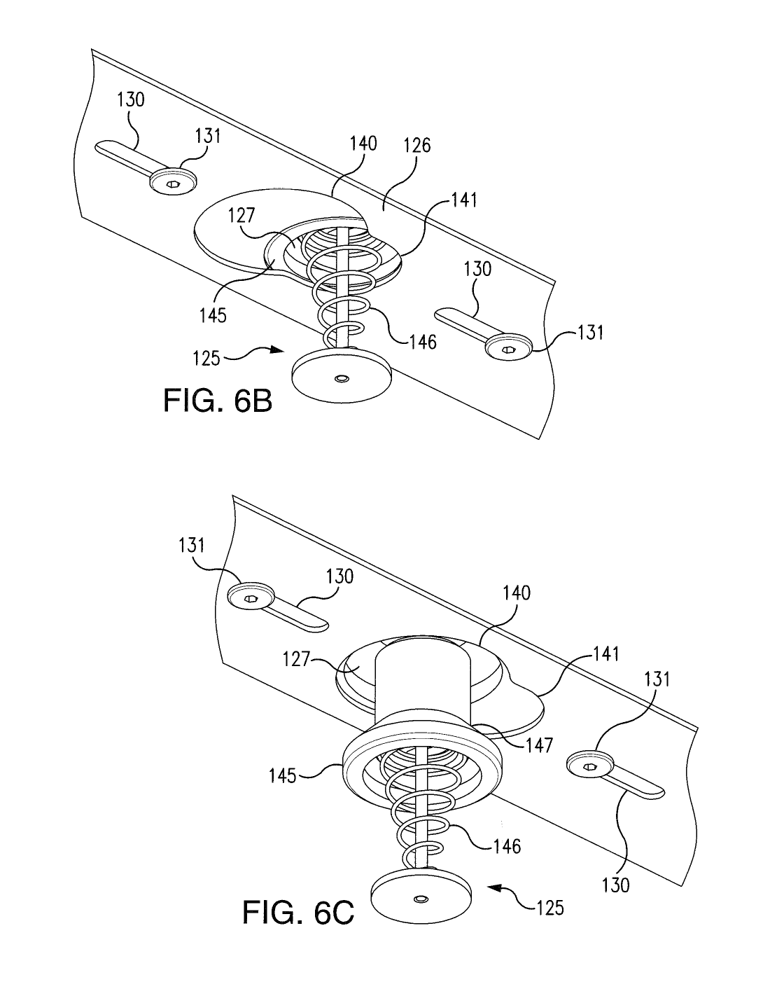

FIGS. 6A-6C illustrate an advantageous arrangement for mounting of lift pins to allow for easy removal and replacement of the lift pins. The figures show a perspective view of the backside 120 of a floor 122 of a reactor which, in a preferred example, is also the lower electrode of the reactor. An opposite side of the floor or electrode 122 includes a surface 124 that provides a support for a substrate during processing. As shown, a plurality of locking members or locking assemblies 126 are provided for releasably holding the lift pins (and associated bushings or alignment members as discussed below) in place within the apertures 127 extending through the substrate support 122. As represented by arrow 130, the locking assemblies 126 are movable horizontally so that they can be moved between locked and unlocked positions.

Although a locking member or locking assembly 126 is provided for each row of lift pins in the illustrated example of FIG. 6A, it is to be understood that various alternatives are possible. For example, a locking member 126 can cover plural rows or even an entire lower surface of the substrate support. Alternately, a locking member could be provided for less than a full row or even only a single lift pin if desired. In the example of FIG. 6A, one or more slots 130 are associated with each of the locking assemblies 126 as discussed further below.

Features of the present invention are particularly advantageous for processing of large substrates, for example, substrates having a size of one square meter or larger. Thus, the substrate supporting surface 124 will have a surface area of one square meter or larger. As should be apparent, to ensure good support of such substrates, a large number of lift pins can be provided. In the arrangement shown, 16 lift pins are provided for one reactor. Thus, where a system includes multiple reactors stacked upon one another, the total number of lift pins in system can become very large. Accordingly, there is a need to be able to efficiently remove and replace the lift pins. Although 16 lift pins are shown in FIG. 6A, the number of lift pins can vary.

FIG. 6B illustrates a lift pin 125 with the locking assembly 126 in the locked position, while FIG. 6C illustrates the unlocked or release position. A fastener or fixing expedient or protrusion 131 is positioned within each slot 130. In addition, in a preferred example, a fastener 131A (FIG. 6A) is provided to hold the assembly 126 in the locked position. When the fastener 131A is removed, the slots 130 can move along the fastener or protrusion 131, with the interaction between slot 130 and fastener 131 providing guiding movement between the locked and unlocked position. With this arrangement the fastener or protrusion can be provided as an allen screw 131, and the fastener 131A can be a screw or nut, for example. In this arrangement, the tightness of the fastener 131 is kept the same (or in other words, it can be fixed), and the removal of fastener 131A releases the assembly 126 to allow movement of same. As an alternative to the use of fastener 131A (or in addition to using fastener 131A), the tightness of fastener 131 can be used to limit or allow movement of the assembly 126. With this alternative, when the fastener 131 is tightened, the assembly 126 is held in place. However, when the fastener is loosened, the assembly can move horizontally with the slot 130 moving relative to the fastener 131. Various expedients can be provided for allowing movement of the plate or assembly 126 and holding the plate in place. For example a lever or latch release or other suitable expedients can be provided.

The assembly 126 further includes an aperture having a first aperture portion 140 and a second aperture portion 141 which is contiguous and extends from the first aperture portion 140. As shown, in the locked position (FIG. 6B), the second aperture portion 141 is aligned with the aperture 127 extending through the substrate support, while in the unlocked position (FIG. 6C) the first aperture portion 140 is aligned with the aperture 127 of the substrate support.

The lift pin 125 is coupled to bushing or alignment member 145, which serves to hold and align the lift pin for movement between extended and retracted positions. As discussed earlier, the lift pins are raised to remove a substrate from loading forks, and then are retracted to deposit the substrate on the substrate support or lower electrode 122 (which also serves as the floor of the reactor). As shown in FIG. 6C, the outer dimension (outer diameter) of the bushing 145 is smaller than the dimension (diameter) of the aperture portion 140. Thus, in the unlocked position (FIG. 6C), the bushing 145 and associated lift pin 125 can be readily removed from the substrate support. By contrast, when the locking assembly 126 is in the locked position (FIG. 6B), the bushing 145 and associated lift pin are held within the aperture 127 of the substrate support or reactor floor. In the locked position, the aperture portion 141 allows the lift pin to be moved between the raised and retracted positions as discussed earlier, however, the position of the bushing and lift spring is secured within aperture 127 of the substrate support.

A spring 146 can be coupled to the lift pin to provide return movement of the lift pin from the raised to the retracted position.

In the unlocked position (FIG. 6C), the aperture portion 146 can also provide for easy insertion/alignment of a bushing 145 and associated lift pin for insertion of a new or replacement pin and bushing assembly. As shown in FIG. 6C, the bushing 145 preferably includes a tapered surface 147 to facilitate placement of the bushing in the aperture 127. Although the substrate support aperture 127 extends completely through the substrate support from one surface to the other so that the lift pin 125 can move between retracted and extended positions, the aperture 127 does not have a constant cross section along its length so that the amount by which the bushing 145 can be inserted into the aperture 127 is limited. For example, the aperture 146 can have a tapered portion of a corresponding shape to the tapered portion 147 of the bushing 145, thereby limiting the amount by which the bushing can be inserted into the aperture 127. Thus, when the bushing is inserted into the aperture 127 and the locking assembly 126 is moved to the locked position, the bushing is held in the proper mounted position. The bushing in turn provides an alignment member for properly positioning and aligning the lift pin during processing. Although the illustrated bushing has a round outer profile and the tapered portion 147 is in the form of a conical section, it is to be understood that other shapes can be used.

As should be apparent, variations and modifications of the disclosed embodiments are possible. It is to be understood that the invention can be practiced in forms other than described in the examples disclosed herein.

What is claimed is:

1. A substrate processing system, comprising:
an outer vacuum chamber comprising:
an outer gas inlet;
an outer gas exhaust outlet;
a plurality of inner vacuum chambers positioned inside of the outer vacuum chamber, wherein the plurality of inner vacuum chambers are arranged adjacent to each other, each of the inner vacuum chambers including a processing volume therein, within which a substrate is processed, each of the inner vacuum chambers further comprising:
a lower portion, the lower portion comprising an exhaust passage to evacuate process gases from the processing volume; and
an upper portion, wherein the upper portion of one inner vacuum chamber is coupled to at least one upper portion of another inner vacuum chamber such that a plurality of upper portions can move vertically together in a coordinated manner, each upper portion comprising a gas inlet to supply process gases to the inner vacuum chamber;
wherein the upper and lower portions provide an enclosure of the processing volume of the inner vacuum chambers, and wherein the upper portion of each inner vacuum chamber is movable vertically relative to the lower portion of each inner vacuum chamber between an open position and a closed position, and wherein in the open position substrates are loaded to and unloaded from the inner vacuum chamber, and in the closed position substrates are processed in the inner vacuum chamber.

2. A substrate processing system according to claim 1, further including an actuator assembly which is connected to respective upper portions of a plurality of the inner vacuum chambers to vertically move the upper portions of the plurality of inner vacuum chambers using the same actuator assembly.

3. A substrate processing system according to claim 2, wherein the lower portion of each inner vacuum chamber comprises a lower electrode, and wherein the upper portion of each inner vacuum chamber comprises an upper electrode which moves with movement of the upper portion.

4. A substrate processing apparatus according to claim 3, wherein in the closed position a gap between the upper electrode and the lower electrode is in a range of 3-10 mm.

5. A substrate processing system according to claim 3, wherein the lower portion of each inner vacuum chamber includes a cooling system, and wherein the lower portion of a first inner vacuum chamber is thermally coupled to an upper portion of a second inner vacuum chamber positioned below the first inner vacuum chamber.

6. A substrate processing system according to claim 2, wherein each inner vacuum chamber includes a plurality of lift pins for loading and unloading of substrates, and wherein lift pins of at least one of the inner vacuum chambers are coupled to the actuator assembly so that said lift pins are moved between raised and retracted positions during at least a portion of the movement of the upper portions between open and closed positions, wherein the lift pins receive a substrate and movement of the lift pins from the raised position to the retracted position places the substrate on a substrate support surface of the lower portion during movement of the upper portions from the open position to the closed position.

7. A substrate processing system according to claim 2, wherein each inner vacuum chamber includes a plurality of lift pins for loading and unloading of substrates, and wherein lift pins of a first inner vacuum chamber are coupled to the upper portion of a second inner vacuum chamber positioned below the first inner vacuum chamber so that said lift pins of the first inner vacuum chamber are moved between raised and retracted positions during at least a portion of the movement of the upper portions of the second inner vacuum chamber between open and closed positions, wherein the lift pins receive a substrate and movement of the lift pins from the raised position to the retracted position places the substrate on a substrate support surface of the lower portion during movement of the upper portion from the open position to the closed position

8. A substrate processing system according to claim 1 wherein the inner vacuum chambers are plasma deposition chambers, wherein the upper portion of each inner vacuum chamber includes a top and a side wall extending downwardly from the top, and wherein the side wall is a side wall of the inner vacuum chamber, and wherein the lower portion is a bottom of the vacuum chamber, and further wherein in the closed position the top, side wall and bottom enclose a reactor volume within which substrates are processed to deposit a film or layer on a substrate positioned on the lower portion, and further wherein the lower portion is configured to support a substrate having a size of one square meter or larger.

9. A substrate processing system, comprising:
a plurality of vacuum chambers disposed adjacent to each other, the vacuum chambers comprising:
a first portion comprising a first electrode that can be coupled to a radio frequency power supply; and
a second portion comprising a second electrode configured to support a substrate thereon;
an actuator assembly that simultaneously moves a plurality of the first portions or a plurality of the second portions of at least a majority of the vacuum chambers in a vertical direction in a single movement;
a gas delivery system that provides process gases to each of the vacuum chambers; and
an exhaust system that removes process gases from each of the vacuum chambers;
wherein the actuator assembly provides relative vertical movement between the first portion and the second portion of each vacuum chamber to provide an open position and a closed position, and wherein in the open position substrates are loaded to and unloaded from the vacuum chambers, and in the closed position substrates are processed in the vacuum chambers.

10. A substrate processing system according to claim 9, wherein each vacuum chamber includes a plurality of lift pins movable between a raised position and a retracted position, and wherein the lift pins receive a substrate, and wherein movement of the lift pins from the raised position to the retracted position places the substrate on the second electrode, and
wherein the actuator assembly is configured to move the lift pins from the raised position to the retracted position during at least a portion of the relative vertical movement between the first portion and the second portion from the open position to the closed position.

11. A substrate processing system according to claim 10, wherein:
the actuator assembly is configured to move the first portion relative to the second portion of each vacuum chamber;
lift pins of a first vacuum chamber are coupled to the actuator assembly by way of a connector so that the lift pins of the first vacuum chamber are raised with raising of the first portion of each vacuum chamber; and
a second vacuum chamber is positioned vertically above the first vacuum chamber, and lift pins of the second vacuum chamber are coupled to the first portion of the first vacuum chamber so that the lift pins of the second vacuum chamber are raised with raising of the first portion of the first vacuum chamber by the actuator assembly.

12. A substrate processing apparatus according to claim 11, wherein the vacuum chambers are plasma deposition chambers, and wherein in the closed position a gap between the first electrode and the second electrode is in a range of from 3-10 mm, and wherein the second electrode is configured to support a substrate having a size of one square meter or larger.

13. A substrate processing system according to claim 12, further including an outer chamber which encloses the plurality of vacuum chambers, and wherein a first vacuum chamber of the plurality of vacuum chambers includes a cooling system which provides cooling to the second portion of the first vacuum chamber; and
wherein a second vacuum chamber of the plurality of vacuum chambers is positioned vertically below the first vacuum chamber, and wherein the first portion of the second vacuum chamber is thermally coupled to the second portion of the first vacuum chamber.

14. A substrate processing system according to claim 13, further including an exhaust outlet for the outer chamber.

15. A substrate processing system according to claim 9, further including an outer chamber which encloses the plurality of vacuum chambers, and wherein a first vacuum chamber of the plurality of vacuum chambers includes a cooling system which provides cooling to the second portion of the first vacuum chamber; and
wherein a second vacuum chamber of the plurality of vacuum chambers is positioned vertically below the first vacuum chamber, and wherein the first portion of the second vacuum chamber is thermally coupled to the second portion of the first vacuum chamber.

16. A substrate processing system according to claim 9, wherein the vacuum chambers are plasma deposition chambers, wherein the first portion of each vacuum chamber includes a top and a side wall extending downwardly from the top, and wherein the side wall is a side wall of the vacuum chamber, and wherein the second portion is a bottom of the vacuum chamber, and further wherein in the closed position the top, side wall and bottom enclose a reactor volume within which substrates are processed to deposit a film or layer on the substrate, and wherein the second portion of each vacuum chamber is configured to support at substrate having a size of one square meter or greater.

17. A substrate processing apparatus comprising:
a substrate support which includes a first surface upon which a substrate is supported, and a second surface on an opposite side of the substrate support than the first surface, wherein the substrate support further includes at least one aperture extending therethrough from the first surface to the second surface;
a lift pin;
an alignment member removably received in the aperture of the substrate support, said alignment member aligning and holding the lift pin therein such that the lift pin is movable in aperture of the substrate holder between a raised position and a retracted position; and
a locking assembly which includes locked and unlocked positions, wherein in the locked position the locking assembly holds the alignment member in the aperture of the substrate support, and in the unlocked position the locking assembly releases the alignment member so that the alignment member and the lift pin can be removed from the aperture of the substrate support.

18. The apparatus according to claim 17, wherein the apparatus is a plasma deposition apparatus;
wherein the substrate support is a lower electrode of the plasma processing apparatus; and
wherein the apparatus further includes an upper electrode.

19. The apparatus according to claim 17, wherein the locking assembly includes a horizontally movable member comprising:
a first aperture portion;
a second aperture portion extending from and contiguous with the first aperture portion;
wherein in the unlocked position the first aperture portion is aligned with the aperture of the substrate holder so that the alignment member can be removed from the aperture of the substrate holder through the first aperture portion; and
wherein in the locked position, the second aperture portion is aligned with the aperture of the substrate holder, and wherein the second aperture portion is configured so that the alignment member cannot be removed therethrough so that the alignment member is held in place the aperture of the substrate holder when the locking assembly is in the locked position.

20. The apparatus according to claim 19, wherein the alignment member includes a bushing having an outer surface which is tapered to facilitate insertion into the aperture of the substrate holder, and wherein the bushing has an outer bushing dimension which is larger than a dimension of the second aperture portion so that the bushing cannot be removed therethrough, and further wherein the outer bushing dimension is smaller than a dimension of the first aperture portion so that the bushing can be removed from the aperture of the substrate support through the first aperture portion when the locking assembly is in the unlocked position.
